(19) United States
(12) Patent Application Publication
(10) Pub. No.: US 2026/0271385 A1
(43) Pub. Date: Sep. 10, 2026

(54) HIGH VOLTAGE FINFET SEMICONDUCTOR DEVICES

(71) Applicant: Micron Technology, Inc., Boise, ID (US)

(72) Inventors: Michael A. Smith, Boise, ID (US); Anna Maria Conti, Milano (IT)

(21) Appl. No.: 19/530,351

(22) Filed: Feb. 5, 2026

Related U.S. Application Data
(60) Provisional application No. 63/769,614, filed on Mar. 10, 2025.

(51) Int. Cl. H10D 84/83; H10D 30/60; H10D 30/62; H10D 62/10; H10D 64/27

(52) U.S. Cl. CPC H10D 84/834; H10D 30/605; H10D 30/6211; H10D 62/124; H10D 64/518; H10D 84/8311; H10D 62/102

(57) ABSTRACT

High-voltage finFET semiconductor devices (and associated systems, devices, and methods) are disclosed herein. In one embodiment, an integrated high-voltage switch includes a high-voltage p-type fin field effect transistor (HVP finFET), a high-voltage depletion fin field effect transistor (HVD finFET), and an active area extending across both the HVP finFET and the HVD finFET. The HVP finFET includes a first plurality of fin trenches formed in the active area, a first plurality of fins defined at least in part by the first plurality of fin trenches, and a first gate extending across the first plurality of fins. The HVD finFET includes a second plurality of fin trenches formed in the active area, a second plurality of fins defined at least in part by the second plurality of fin trenches, and a second gate extending across the second plurality of fins.

### CROSS-REFERENCE TO RELATED APPLICATION(S)

The present application claims priority to U.S. Provisional Patent Application No. 63/769,614, filed Mar. 10, 2025, the disclosure of which is incorporated herein by reference in its entirety.

### TECHNICAL FIELD

The present disclosure relates generally to high-voltage semiconductor devices. For example, several embodiments of the present technology described in detail below relate generally to integrated high-voltage switches that employ fin field effect transistor (finFET) devices, such as high-voltage p-type (HVP) finFETs and a high-voltage depletion (HVD) finFETs integrated into a single active area.

### BACKGROUND

There is industry demand for semiconductor devices with smaller footprints. For example, advanced nodes of three-dimensional (3D) NAND memory technology demand increasingly smaller footprints for control circuitry to enable higher density and lower cost memory devices. As memory density increases, the area available for peripheral circuitry such as high-voltage switches becomes more constrained. High-voltage switches are components in memory devices that are commonly used for functions like block selection and programming operations.

Traditional planar high-voltage switch designs face challenges in scaling to smaller dimensions while maintaining adequate performance and reliability. For example, as the widths of high-voltage switches decrease, leakage due to Fowler-Nordheim tunneling may become more pronounced, especially at edges of the switches. In other words, reducing widths of planar high-voltage switches can result in edge-dominated behavior and/or in an unacceptable reduction in performance and reliability. Therefore, in order to meet industry demand for smaller peripheral circuitry footprints, there is a need for non-planar high-voltage switch designs.

### BRIEF DESCRIPTION OF FIGURES

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 illustrates a partially schematic top view of a high-voltage semiconductor device configured in accordance with various embodiments of the present technology.

FIG. 2 illustrates a partially schematic, cross-sectional side view of part of a high-voltage semiconductor device configured in accordance with various embodiments of the present technology.

FIG. 3 illustrates a partially schematic, cross-sectional side view of part of another high-voltage semiconductor device configured in accordance with various embodiments of the present technology.

FIG. 4 illustrates a partially schematic top view of a high-voltage semiconductor device configured in accordance with various embodiments of the present technology.

FIG. 5 illustrates a partially schematic top view of adjacent high-voltage semiconductor devices configured in accordance with various embodiments of the present technology.

### DETAILED DESCRIPTION

The present technology is generally directed to finFET designs for high-voltage semiconductor devices. For example, several embodiments of the present technology described in detail below are directed to finFET designs for integrated high-voltage switches, such as integrated high-voltage switches that each include a high-voltage p-type (HVP) fin field effect transistor (finFET) and a high-voltage depletion (HVD) finFET sharing a same active area. Integrated high-voltage switches, however, are merely used as an example of the present technology. Stated another way, the present technology is not limited to integrated high-voltage switches. Indeed, aspects and principles of the present technology described herein can be utilized in other high-voltage semiconductor devices, such as HVP finFETs and/or HVD finFETs that include their own active areas.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Overview

As discussed above, there is industry demand for smaller semiconductor device footprints. In response, many techniques have been explored to reduce the area of high-voltage devices. Some approaches have involved integrating multiple, planar high-voltage devices, such as high-voltage depletion (HVD) transistors and high-voltage p-type (HVP) transistors, into a single active area. While this integration strategy has provided some area savings, reliability and performance issues have been observed when attempting to achieve further device scaling with these planar designs.

For example, in integrated high-voltage switches that employ planar high-voltage p-type (HVP) field effect transistors, the inventors have observed an increase in leakage current leading to threshold voltage shifts in the planar HVP field effect transistors, especially as the widths of the planar HVP field effect transistors are reduced. Without being bound by theory, it is expected that the increase in leakage current is due at least in part to Fowler-Nordheim tunneling that occurs at edges of the switches, such as edges of gates of the planar HVP field effect transistors. Because the increase in leakage current poses an unacceptable risk of reliability and performance issues, the inventors have identified a need for other non-planar designs for high-voltage semiconductor devices in order to meet industry demands for high-voltage devices with smaller footprints.

To this end, the inventors have developed high-voltage semiconductor devices (e.g., integrated high-voltage switches) that employ high-voltage fin field effect transistors to achieve reduced footprints, especially in comparison to many high-voltage semiconductor devices that employ planar device designs. For example, several embodiments of the present technology described in detail below are directed to integrated high-voltage switches that each employ a high-voltage p-type (HVP) fin field effect transistor (finFET) and/or a high-voltage depletion (HVD) finFET integrated into a single active area. The HVP finFET and/or the HVD finFET can include multiple fin trenches arranged in parallel in the active area, with fins positioned between the trenches. In addition, the HVP finFET and/or the HVD finFET can include a gate that extends across the fins and includes gate fins positioned within one or more of the fin trenches (e.g., between adjacent fins formed in the active area).

Such finFET-based designs are expected to offer several advantages over planar designs. For example, by utilizing a three-dimensional fin structure, the present technology is expected to achieve further scaling of device widths without the edge-dominated behavior and reliability issues discussed above that are associated with reducing widths of planar designs. In particular, without being bound by theory, it is expected that the fin structure will help mitigate Fowler-Nordheim tunneling effects at device edges, allowing for narrower overall device widths while maintaining device reliability and performance. Additionally, the (a) integration of both HVP finFETs and HVD finFETs into a single active area and/or (b) the ability to optimize N-well depth and/or dosing are expected to contribute to a reduced overall footprint, further addressing industry demand for smaller high-voltage devices.

### B.Selected Embodiments of High-Voltage finFET Semiconductor Devices, and Associated Systems, Devices, and Methods

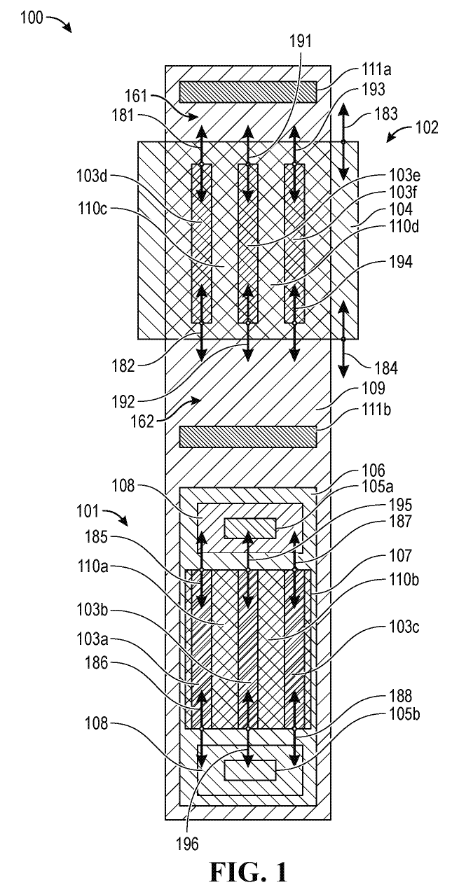

FIG. 1 illustrates a partially schematic, top orthogonal view of a high-voltage semiconductor device 100 configured in accordance with various embodiments of the present technology. As shown, the high-voltage semiconductor device 100 includes a high-voltage p-type fin field effect transistor 101 ("the HVP finFET 101") and a high-voltage depletion fin field effect transistor 102 ("the HVD finFET 102"). The HVP finFET 101 and the HVD finFET 102 can be integrated into a same active area 109. For example, the active area 109 shown in FIG. 1 can be a continuous region that extends across both the HVP finFET 101 and the HVD finFET 102. In some such embodiments, the high-voltage semiconductor device 100 can be an integrated high-voltage switch.

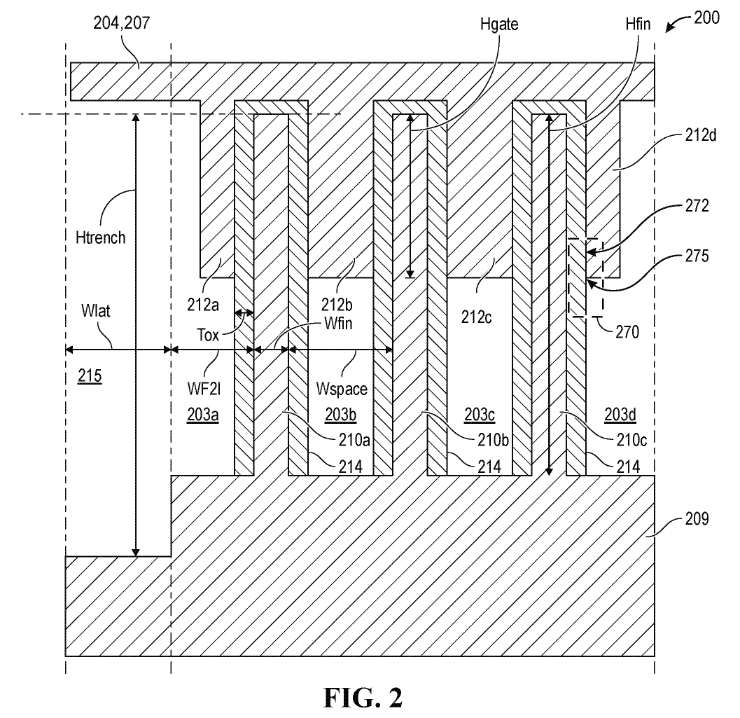

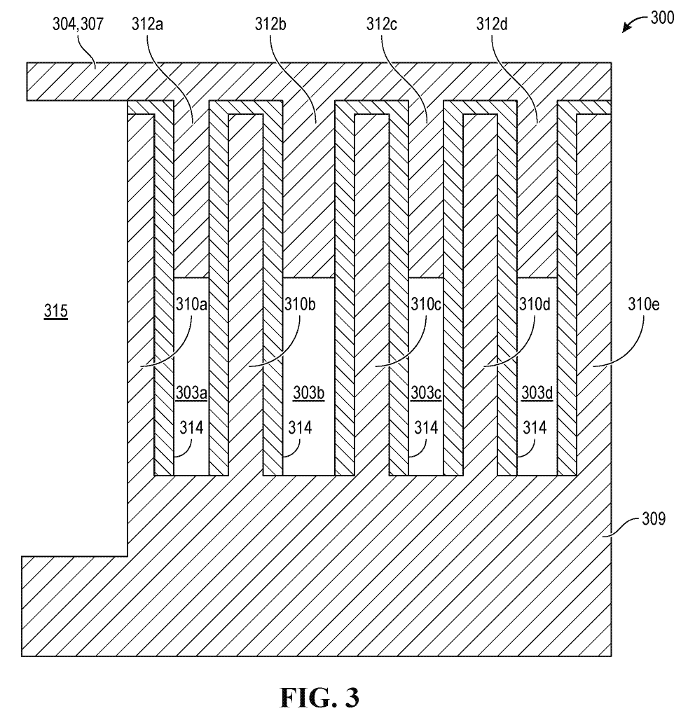

The HVP finFET 101 can include a high-voltage N-well 106, source/drain P+ implant regions 108, a first contact 105a, and a second contact 105b. The HVP finFET 101 of FIG. 1 further includes a plurality of fin trenches 103 (identified individually in FIG. 1 as first fin trench 103a, second fin trench 103b, and third fin trench 103c) formed in the active area 109. As discussed in greater detail below with reference to FIGS. 2 and 3, portions of the active area 109 that remain after forming the fin trenches 103 can at least partially define fins 110 (identified individually in FIG. 1 as first fin 110a and second fin 110b) of the HVP finFET 101. Thus, at least some of the fins 110 can be positioned between pairs of adjacent fin trenches 103. In the illustrated embodiment, the fins 110a and 110b are generally arranged in parallel with one another.

In the illustrated embodiment, the fin trenches 103a-103c are constrained to a channel of the HVP finFET 101. For example, each of the fin trenches 103a-103c can be dimensioned such that it fully fits within an area between the contact 105a and the contact 105b. As a result, the fins 110a and 110b defined at least in part by the fin trenches 103a-103c can similarly be constrained to the channel of the HVP finFET 101 and/or be dimensioned such that they fully fit within the area between the contact 105a and the contact 105b.

In the illustrated embodiment, the fin trenches 103a-103c are uniformly dimensioned, and the fins 110a, 110b are uniformly dimensioned. In other embodiments, any one or more of the fin trenches 103 and/or any one or more of the fins 110s of the HVP finFET 101 can be differently dimensioned from one another and/or from the dimensions shown in FIG. 1. For example, as shown by arrows 185-188, 195 and 196 in FIG. 1, the lengths (measured in a direction extending generally from the contact 105b toward the contact 105a) of any one or more of the fin trenches 103 can vary from the lengths of the fin trenches 103a-103c shown in FIG. 1. As a result, the lengths of some of the fins 110 defined at least in part by one or more of the fin trenches 103 may vary from one another and/or from the lengths of the fins 110a, 110b shown in FIG. 1. Additionally, or alternatively, other dimensions (e.g., width and/or depth) of the fin trenches 103 and/or of the fins 110 can vary from one another and/or from corresponding dimensions shown in FIG. 1.

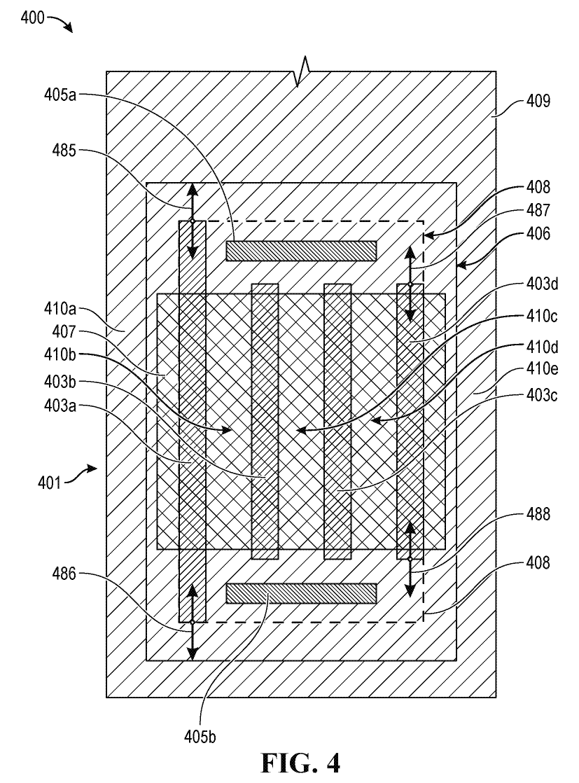

As a specific example, one or both of the outer fin trenches 103a and 103c shown in FIG. 1 can be extended beyond the channel of the HVP finFET 101, such as to the ends of the P+ implant regions 108 on sides of the contacts 105a, 105b opposite the fins 110a, 110b. In such an arrangement, the outer fin trench 103a and/or the outer fin trench 103b is/are expected to make a width (measured in a direction extending generally from the fin trench 103a toward the fin trench 103b) of the HVP finFET 101 more well-defined along all or a subset of the length of the HVP finFET 101. An example of a similar arrangement is illustrated in FIG. 4 and described in greater detail below.

In some embodiments, one or both of the outer fin trenches 103a and 103b can serve as isolation regions (e.g., shallow trench isolation (STI) regions, local deep trench (LDT) isolation regions). For example, the outer fin trenches 103a and/or 103b can have depths (measured in a direction extending generally into the page in FIG. 1) that is equal to or greater than one or more depths of one or more inner fin trenches, such as equal to or greater than a depth of the fin trench 103b of FIG. 1. In other embodiments, the depths of the outer fin trenches 103a and/or 103b can have depths that are shallower than one or more depths of one or more inner fin trenches, such as the depth of the fin trench 103b. Additionally, or alternatively, one or more STI regions and/or LDT isolation regions can be formed laterally adjacent the N-well 306 and used (in addition to or in lieu of the outer fin trenches 103a and/or 103b) to isolate the N-well 306 and/or the HVP finFET 101 from other devices or components.

As shown in FIG. 1, the HVP finFET 101 further includes a gate 107 positioned over all or a subset of the fin trenches 103 and/or over all or a subset of the fins 110. As discussed in greater detail below with reference to FIG. 2, the gate 107 can include one or more gate fins. The gate fin(s) of the gate 107 can be generally aligned with and/or positioned within the fin trenches 103. For example, the gate 107 of FIG. 1 can include three gate fins, with each gate fin positioned in a different one of the fin trenches 103a-103c formed in the active area 109. As a result, the fin 110a can be flanked by a first pair of gate fins of the gate 107, and the fin 110b can be flanked by a second pair of gate fins of the gate 107. Stated another way, when positioned at least partially within one of the fin trenches 103a-103c, a gate fin of the gate 107 can be flanked or surrounded by portions (e.g., one or more fins 110 and/or a boundary portion) of the active area 109 on at least two sides.

As discussed above, the fins 110a and 110b can be flanked on each side by gate fins of the gate 107. Thus, the fins 110a and 110b can be referred to herein as "active fins" of the HVP finFET 101. In some embodiments, active fins can be connected to the source/drain P+ regions 108 of the HVP finFET 101. By contrast, a first boundary portion of the active area 109 positioned to the left of the fin trench 103a in FIG. 1 is flanked by a gate fin of the gate 107 on only one side of the first boundary portion, and a second boundary portion of the active area 109 positioned to the right of the fin trench 103c in FIG. 1 is flanked by a gate fin of the gate 107 on only one side of the second boundary portion. Thus, the first and second boundary portions can be referred to herein as "half fins" or as "inactive fins."

In the illustrated embodiment, the gate 107 fits within a footprint of the N-well 106. More specifically, a width of the gate 107 fits within a width of the N-well 106 such that, for example, (1) a left boundary of the N-well 106 is positioned between (a) a left boundary of the active area 109 and (b) a left boundary of the gate 107 and/or a left edge of the fin trench 103a, and (2) a right boundary of the N-well 106 is positioned between (a) a right boundary of the active area 109 and (b) a right boundary of the gate 107 and/or a right edge of the fin trench 103a. In other embodiments, the gate 107 can be positioned and/or dimensioned such that, for example, (i) a left boundary of the gate 107 extends beyond the left boundary of the N-well 106 and/or the left boundary of the active area 109, and/or (ii) a right boundary of the gate 107 extends beyond the right boundary of the N-well 106 and/or the right boundary of the active area 109.

In addition, in the illustrated embodiment, a length of the gate 107 fits within a length of the N-well 106. More specifically, the gate 107 has a length that corresponds to a length of one or more of the fin trenches 103a-103c. In other embodiments, the gate 107 can be positioned and/or dimensioned such that, for example, (1) a top boundary of the gate 107 closest the contact 105a (i) is positioned between the contact 105a and a top edge of one or more of the fin trenches 103a-103c, (ii) is aligned with a top edge of one or more of the fin trenches 103a-103c, and/or (iii) is positioned on a side of a top edge of one or more of the fin trenches 103a-103c opposite the contact 105a; and (2) a bottom boundary of the gate 107 closest the contact 105b (i) is positioned between the contact 105b and a bottom edge of one or more of the fin trenches 103a-103c, (ii) is aligned with a bottom edge of one or more of the fin trenches 103a-103c, and/or (iii) is positioned on a side of a bottom edge of one or more of the fin trenches 103a-103c opposite the contact 105b.

Dimensions of gate fins of the gate 107 can be uniform or vary from one another, similar to the dimensions of the fin trenches 103 and the fins 110 described above. In some embodiments, dimensions of a gate fin of the gate 107 can be constrained to be less than or equal to dimensions of a corresponding one of the fin trenches 103. In these and other embodiments, dimensions of a gate fin can be less than, greater than, or equal to corresponding dimensions of a fin 110, such as a fin 110 positioned adjacent the gate fin in the HVP finFET 101.

Although the HVP finFET is shown in FIG. 1 and/or described above as having three fin trenches 103, two fins 110, and three gate fins, the present technology is not so limited. Indeed, HVP finFETs configured in accordance with other embodiments of the present technology can include (a) a different number of fin trenches (e.g., one fin trench, two fin trenches, or four or more fin trenches), (b) a different number of fin (e.g., one fin or three or more fins), and/or (c) a different number of gate fins (e.g., one gate fin, two gate fins, or more than three gate fins.

In some embodiments, a length of the high-voltage semiconductor device 100 can depend at least in part on characteristics (e.g., doping and depth) of the N-well 106. Thus, the depth and doping concentration of the N-well 106 can be optimized to reduce the overall length of the high-voltage semiconductor device 100 (or to achieve a desired length of the high-voltage semiconductor device 100) while maintaining desired electrical characteristics, such as of the HVP finFET 101. For example, the depth and/or doping characteristics of the N-well 106 may be optimized to reduce the overall length of the high-voltage semiconductor device 100 while reducing, minimizing, or eliminating HVD drain-to-N-well leakage that can potentially occur between the N-well 106 of the HVP finFET 101 and a drain of the HVD finFET 102.

Referring now to the HVD finFET 102 of the high-voltage semiconductor device 100, the HVD finFET 102 can include a contact 111a, a contact 111b, fin trenches 103 (identified individually in FIG. 1 as fourth fin trench 103d, fifth fin trench 103e, and sixth fin trench 103f) formed in the active area 109, and fins 110 (identified individually in FIG. 1 as third fin 110c and fourth fin 110d) positioned between pairs of adjacent fin trenches 103. Similar to the fins 110a and 110b of the HVP finFET 101 described above, the fins 110c and 110d of the HVD finFET 102 can be portions of the active area 109 that remain after forming the fin trenches 103d-103f.

In the illustrated embodiment, the fin trenches 103d-103f are uniformly dimensioned, and the fins 110c and 110d are uniformly dimensioned. In addition, the fin trenches 103d-103f and the fins 110c and 110d include dimensions generally similar to the fin trenches 103a-103c and the fins 110a and 110b, respectively, of the HVP finFET 101. In other embodiments, any one or more of the fin trenches 103 and/or any one or more of the fins 110 of the HVD finFET 102 can be differently dimensioned (a) from one another, (b) from the dimensions shown in FIG. 1, and/or (c) from the dimensions of any one or more of the fin trenches 103 and/or any one or more of the fins 110 of the HVP finFET 101. For example, as shown by arrows 181, 182, and 191-194 in FIG. 1, the lengths (measured in a direction extending generally from the contact 111b toward the contact 111a) of any one or more of the fin trenches 103 can vary from the lengths of the fin trenches 103d-103f shown in FIG. 1. As a result, the lengths of some of the fins 110 defined at least in part by one or more of the fin trenches 103 may vary from one another and/or from the lengths of the fins 110c, 110d shown in FIG. 1. Additionally, or alternatively, other dimensions (e.g., width and/or depth) of the fin trenches 103 and/or of the fins 110 can vary from one another, from corresponding dimensions shown in FIG. 1, and/or from the dimensions of any one or more of the fin trenches 103 and/or any one or more of the fins 110 of the HVP finFET 101.

The HVD finFET 102 further includes lightly doped drain (LDD) regions 161 and 162. In the illustrated embodiment, the fin trenches 103d-103f are constrained to a channel of the HVD finFET 102 between the LDD regions 161 and 162. Thus, the channel of the HVD finFET 102 can be finned while the LDD regions 161 and 162 are planar. In other embodiments, the LDD region 161 and/or the LDD region 162 may be finned. For example, one or more of the fin trenches 103d-103f may be extended into the LDD regions 161 and/or 162 (as indicated by arrows 181, 182, and 191-194 in FIG. 1) such that the channel of the HVD finFET 102 and either or both of the LDD regions 161 and 162 are finned.

As shown in FIG. 1, the HVP finFET 101 further includes a gate 104 positioned over all or a subset of the fin trenches 103 and/or over all or a subset of the fins 110. As discussed in greater detail below with reference to FIG. 2, the gate 104 can include one or more gate fins. The gate fin(s) of the gate 104 can be generally aligned with and/or positioned within the fin trenches 103. For example, the gate 104 of FIG. 1 can include three gate fins, with each gate fin positioned in a different one of the fin trenches 103d-103f formed in the active area 109. As a result, the fin 110c can be flanked by a first pair of gate fins of the gate 104, and the fin 110d can be flanked by a second pair of gate fins of the gate 104. Stated another way, when positioned at least partially within one of the fin trenches 103d-103f, a gate fin of the gate 104 can be flanked or surrounded by portions (e.g., one or more fins 110 and/or a boundary portion) of the active area 109 on at least two sides.

As discussed above, the fins 110c and 110d can be flanked on each side by gate fins of the gate 104. Thus, the fins 110c and 110d can be referred to herein as "active fins" of the HVD finFET 102. By contrast, a third boundary portion of the active area 109 positioned to the left of the fin trench 103d in FIG. 1 is flanked by a gate fin of the gate 104 on only one side of the third boundary portion, and a fourth boundary portion of the active area 109 positioned to the right of the fin trench 103f in FIG. 1 is flanked by a gate fin of the gate 104 on only one side of the fourth boundary portion. Thus, the third and fourth boundary portions can be referred to herein as "half fins" or as "inactive fins."

In the illustrated embodiment, the gate 104 is positioned over a channel of the HVD finFET 102 and has a length such that the HVD finFET 102 extends beyond the fin trenches 103d-103f toward the contacts 111a and 111b. In some embodiments, the gate 104 may extend over the LDD regions 161 and/or 162, as indicated by arrows 183 and 184 in FIG. 1. In some embodiments, the gate 104 may not extend over the LDD regions 161 and/or 162, may not extend beyond the fin trenches 103d-103f, and/or may be include dimensions that correspond to and/or are aligned with the fin trenches 103d-103f. For example, the gate 104 can be positioned and/or dimensioned such that, for example, a top boundary of the gate 104 closest the contact 111a (i) is positioned between the contact 111a and a top edge of one or more of the fin trenches 103d-103f, (ii) is aligned with a top edge of one or more of the fin trenches 103d-103f, and/or (iii) is positioned on a side of a top edge of one or more of the fin trenches 103d-103f opposite the contact 111a. Similarly, a bottom boundary of the gate 104 closest the contact 111b (i) may be positioned between the contact 111b and a bottom edge of one or more of the fin trenches 103d-103f, (ii) may be aligned with a bottom edge of one or more of the fin trenches 103d-103f, and/or (iii) may be positioned on a side of a bottom edge of one or more of the fin trenches 103d-103f opposite the contact 111b.

Dimensions of gate fins of the gate 104 can be uniform or vary from one another, similar to the dimensions of the fin trenches 103 and the fins 110 of the HVD finFET 102 described above. In some embodiments, dimensions of a gate fin of the gate 104 can be constrained to be less than or equal to dimensions of a corresponding one of the fin trenches 103. In these and other embodiments, dimensions of a gate fin of the gate 104 can be less than, greater than, or equal to corresponding dimensions of a fin 110, such as a fin 110 positioned adjacent the gate fin in the HVD finFET 102.

In some embodiments, one or more of the outer fin trenches 103d and/or 103f can serve as isolation regions (e.g., shallow trench isolation (STI) regions, local deep trench (LDT) isolation regions). Additionally, or alternatively, one or more STI regions and/or LDT isolation regions can be formed laterally adjacent the HVD finFET 102 and used to isolate the HVD finFET 102 from other devices or components.

While the HVD finFET 102 is shown in FIG. 1 and/or described above as having three fin trenches 103, two fins 110, and three gate fins, the present technology is not so limited. In other embodiments, HVD finFETs configured in accordance with the present technology may include a different number of fin trenches (e.g., one fin trench, two fin trenches, or four or more fin trenches), a different number of fins (e.g., one fin or three or more fins), and/or a different number of gate fins (e.g., one gate fin, two gate fins, or more than three gate fins).

Furthermore, while the high-voltage semiconductor device 100 is shown in FIG. 1 and described above as having the HVP finFET 101 and the HVD finFET 102, high-voltage semiconductor devices configured in accordance with other embodiments of the present technology can omit the HVP finFET 101 or the HVD finFET 102. For example, a high-voltage semiconductor device configured in accordance with other embodiments of the present technology can include only an HVP finFET (e.g., similar to the HVP finFET 101 described above) or only an HVD finFET (e.g., similar to the HVD finFET 102 described above). As another example, a high-voltage semiconductor device configured in accordance with the present technology can include an HVP finFET (e.g., similar to the HVP finFET 101 of described above) and a planar HVD FET (e.g., an HVD FET that includes a planar channel and/or LDD regions as opposed to a finned channel and/or LDD regions). As still another example, a high-voltage semiconductor device configured in accordance with the present technology can include an HVD finFET (e.g., similar to the HVD finFET 102 described above) and a planar HVP FET (e.g., an HVP FET that includes a planar channel as opposed to a finned channel).

FIG. 2 illustrates a partially schematic, cross-sectional side view of part of a high-voltage semiconductor device 200 configured in accordance with various embodiments of the present technology. The part of the high-voltage semiconductor device 200 can be part of an HVP finFET (e.g., the HVP finFET 101 of FIG. 1 or another HVP finFET configured in accordance with the present technology) or part of an HVD finFET (e.g., the HVD finFET 102 of FIG. 1 or another HVD finFET configured in accordance with the present technology). As shown, the high-voltage semiconductor device 200 includes a plurality of fins 210 (identified individually in FIG. 2 as fins 210a-210c) formed in an active area 209, and a gate 204, 207 positioned over the plurality of fins 210.

The fins 210a-210c can be formed by forming fin trenches 203 (identified individually in FIG. 2 as fin trenches 203a-203d) in the active area 209. In the illustrated embodiment, depths of the fin trenches 203a-203d are uniform. In other embodiments, depths of the fin trenches 203a-203d can differ from one another. Example depths for the fin trenches 203a-203d can include approximately 2000 Angstroms to approximately 5000 Angstroms, such as approximately 3800 Angstroms. As discussed above, the fin trenches 203a-203d can at least partially define the fins 210a-210c. Thus, continuing with the example depths for the fin trenches 203a-203d provided above, example heights Hfin for the fins 210a-210c can include approximately 2000 Angstroms to approximately 5000 Angstroms, such as approximately 3800 Angstroms.

In some embodiments, the fin trenches 203a-203d can be formed in the active area 209 such that the fins 210a-210c are formed with certain widths and/or are arranged at a certain pitch. For example, the fin trenches 203a-203d can be formed in the active area 209 such that (a) the fins 210a-210c each have a width Wfin of approximately 50nm to approximately 100nm (e.g., approximately 80nm) and/or (b) are arranged at a pitch of approximately 200nm to approximately 300nm (e.g., approximately 235nm or approximately 250nm). Continuing with these examples, a distance Wspace between adjacent fins can be approximately 100nm to approximately 250nm (e.g., approximately 155nm or approximately 170nm). Although illustrated with uniform widths and as being arranged at a uniform pitch, fins formed in the active area 209 in other embodiments of the present technology can have differing widths and/or be arranged at differing pitches (e.g., such that distances between adjacent fins are not uniform).

As shown in FIG. 2, a trench 215 can be formed to the left of the fin trench 203a and can be used for isolating the high-voltage semiconductor device 200 from adjacent devices or components. In some embodiments, the trench 215 can be a shallow trench isolation (STI) region or a local deep trench (LDT) isolation region. In these and other embodiments, the trench 215 can be a fin trench (e.g., similar to the fin trenches 203a-203d) formed in the active area 209. Example depths Htrench for the trench 215 can include approximately 2000 Angstroms to approximately 9000 Angstroms, such as approximately 3800 Angstroms in embodiments in which the trench 215 is configured as an STI region or approximately 7500 Angstroms in embodiments in which the trench 215 is configured as an LDT isolation region. In general, depths Htrench for the trench 215 can be greater than or equal to heights Hfin for the fins 210a-210c. Example widths Wlat for the trench 215 can include approximately 200nm to approximately 300nm, such as approximately 250nm.

As also shown in FIG. 2, the fin trenches 203a and/or 203d can be formed at edges of the active area 209. As a result, the outer fins 210a and/or 210c can be positioned at locations laterally offset from the edges of the active area 209. For example, due to formation of the trench 203a at an edge of the active area 209 corresponding to a right edge of the trench 215 in FIG. 2, the fin 210a can be positioned at a location that is laterally offset from the right edge of the trench 215, such as by a distance WF2I (e.g., approximately 100nm to approximately 250nm, such as approximately 155nm). In addition, due to formation of the trench 203d at a right edge of the active area 209 in FIG. 2, the fin 210d can be positioned at a location that is laterally offset from the right edge of the active area 209 by a distance (e.g., approximately 100nm to approximately 250nm, such as approximately 155nm). Stated another way, the fin 210a and/or the fin 210c is/are not aligned with an edge of the active area 209. In other embodiments, fin trenches can be formed in active area at locations laterally offset from edges of the active area such that fins are aligned with edges of the active area. An example of such an arrangement is illustrated in FIG. 3 and described in greater detail below.

In the illustrated embodiment, each of the fins 210a-210c can be lined with an oxide material 214. In some embodiments, the oxide material 214 can have a thickness Tox of approximately 300 Angstroms to approximately 500 Angstroms, such as about 390 Angstroms. In some embodiments, the gate oxide material 214 can additionally line surfaces of the active area 209 located at bottoms of one or more of the fin trenches 203a-203dand/or at a bottom of the trench 215.

Referring now to the gate 204, 207 of the high-voltage semiconductor device 200 that is positioned over the active area 209, the gate 204, 207 can include a plurality of gate fins 212 (identified individually in FIG. 2 as gate fins 212a-212d). As shown, the gate fins 212a-212d are dimensioned and the gate 204, 207 is positioned such that the gate fins 212a-212d are each arranged within a corresponding one of the fin trenches 203a-203d. In the illustrated embodiment, the gate fins 212a-212d include differing widths. In other embodiments, the gate fins 212a-212d can include uniform widths. Additionally, the gate fins 212a-212b are illustrated in FIG. 2 as having a uniform height Hgate (e.g., approximately 2000 Angstroms to approximately 4000 Angstroms, such as approximately 3400 Angstroms). In other embodiments, heights of one or more of the gate fins 212a-212d can vary from one another. In general, a height Hfin of one of the fins 210a-210c can be greater than or equal to a height Hgate of one of the gate fins 212a-212d plus a thickness Tox of the gate oxide material 214. For example, in some embodiments, heights Hgate of the gate fins 212a-212d can be approximately equivalent to heights Hfin of the fins 210a-210c minus a thickness Tox of the gate oxide material 214 lining the fins 210a-210c. As another example, in embodiments in which a height Htrench of the trench 215 is approximately equal to the heights Hfin of the fins 210a-210c, the heights Hgate of the gate fins 212a-212d can be significantly smaller than the heights Hfin of the fins 210a-210c. As still another example, in embodiments in which a height Htrench of the trench 215 is significantly greater than the heights Hfin of the fins 210a-210c, the heights Hgate of the gate fins 212a-212d can be approximately equal to or less than the heights Hfin of the fins 210a-210c.

As shown in FIG. 2, at least when the gate fins 212a-212d are positioned within the fin trenches 203a-203d, each of the fins 210a-210c are flanked by two of the gate fins 212a-212d. Stated another way, the gate 204, 207 is positioned such that the gate 204, 207 straddles each of the fins 210a-210c. As such, the fins 210a-210c can each be active fins. Referring to the fin 210a as an example, in this arrangement, the gate fins 212a and 212b of the gate 204, 207 are positioned on opposite sides of the 210a and are separated from the fin 210a by the oxide material 214.

While the high-voltage semiconductor device 200 is shown in FIG. 2 and/or described above as having four fin trenches 203a-203d, a single trench 215, three fins 210a-210c, zero inactive fins, three active fins 210a-210c, and four gate fins 212a-212d, the present technology is not so limited. In other embodiments, high-voltage semiconductor devices configured in accordance with the present technology may include a different number of fin trenches (e.g., one fin trench, two fin trenches, three fin trenches, or five or more fin trenches), a different number of trenches (e.g., more than one trench or isolation region similar to the trench 215), a different number of fins (e.g., one fin, two fins, or four or more fins), a different number of inactive fins (e.g., one or more inactive fins), a different number of active fins (e.g., one active fin, two active fins, or four or more active fins), and/or a different number of gate fins (e.g., one gate fin, two gate fins, three gate fins, or more than four gate fins).

The finFET design of the high-voltage semiconductor device 200 illustrated in FIG. 2 is expected to offer several advantages over planar designs. For example, in comparison to planar designs, the finFET design is expected to reduce a total width of the high-voltage semiconductor device 200 while maintaining or improving performance (per planar area) as a result of the three-dimensional characteristics intrinsic to finFET designs. This is particularly beneficial as it can help meet industry demands for smaller footprints in high-voltage semiconductor devices.

As another example, the finFET design eliminates certain geometries used in planar designs that are believed to result in Fowler-Nordheim tunneling issues as device width shrinks. More specifically, in planar designs an edge or corner of a gate is often aligned with an edge or corner of a channel of a high-voltage semiconductor device. Without being bound by theory, it is expected that this geometry results in edge-dominated behavior of electric fields as a width of a planar high-voltage semiconductor device is reduced, leading to increased Fowler-Nordheim tunneling, shifting of threshold voltages (e.g., of planar HVP devices), and/or potential performance and reliability issues.

By contrast, it is expected that finFET designs for high-voltage semiconductor devices can reduce, minimize, or eliminate such edge-dominated behavior at least in part because finFET designs do not include the problematic geometries present in planar designs. In particular, referring to region 270 illustrated in FIG. 2, a corner 275 of the gate 204, 207 is shown (corresponding to a corner of the gate fin 212d). As shown, rather than this corner 275 of the gate 204, 207 being arranged near a corner of a channel of the high-voltage semiconductor device 200 (which would be a geometry similar to that which is present in planar designs and which is expected to lead to edge-dominated behavior as widths shrink), the corner 275 is arranged proximate a flat or planar surface 272 of the fin 210c. Such an arrangement is expected to avoid edge-dominated behavior as a width of the high-voltage semiconductor device 200 is reduced, thereby enabling smaller footprints for the high-voltage semiconductor device 200 while maintaining or improving device performance and/or reliability.

FIG. 3 illustrates a partially schematic, cross-sectional side view of part of another high-voltage semiconductor device 300 configured in accordance with various embodiments of the present technology. The part of the high-voltage semiconductor device 300 can be part of an HVP finFET (e.g., the HVP finFET 101 of FIG. 1 or another HVP finFET configured in accordance with the present technology) or part of an HVD finFET (e.g., the HVD finFET 102 of FIG. 1 or another HVD finFET configured in accordance with the present technology). As shown, the part of the high-voltage semiconductor device 300 is generally similar to the part of the high-voltage semiconductor device 200 illustrated in FIG. 2. For example, the high-voltage semiconductor device 300 includes a plurality of fins 310 (identified individually in FIG. 3 as fins 310a-310e) formed at least in part by forming a plurality of fin trenches 303 (identified individually in FIG. 3 as fin trenches 303a-303d) in an active area 309; a gate 304, 307 positioned over the plurality of fins 310 and including a plurality of fin gates 312 (identified individually in FIG. 3 as fin gates 312a-312d); an oxide material 314 lining the fins 310a-310e; and a trench 315 (e.g., an STI region, an LDT isolation region, a fin trench).

In contrast with the high-voltage semiconductor device 200 of FIG. 2, however, the fin trenches 303a and 303d are formed at locations laterally offset from edges of the active area 309 of the high-voltage semiconductor device 300. As a result, the fins 310a and 310e of the high-voltage semiconductor device 300 are positioned at (and aligned with) the edges of the active area 309. In addition, each of the fins 310a and 310e is flanked by a gate fin (e.g., the gate fin 312a and the gate fin 312d, respectively) of the gate 304, 307 on only one side. Thus, the high-voltage semiconductor device 300 includes two inactive fins (the fins 310a and 310e) and three active fins (the fins 310b-310d). Furthermore, each of the fins 310a and 310e is lined with oxide material 314 on only one side and its top (e.g., as opposed to on both sides and its top). In other embodiments, each of the fins 310a and 310e can be lined with oxide material 314 on both sides and its top.

While the high-voltage semiconductor device 300 is shown in FIG. 3 and/or described above as having four fin trenches 303a-303d, a single trench 315, five fins 310a-310e, two inactive fins 310a and 310e, three active fins 310b-310d, and four gate fins 312a-312d, the present technology is not so limited. In other embodiments, high-voltage semiconductor devices configured in accordance with the present technology may include a different number of fin trenches (e.g., one fin trench, two fin trenches, three fin trenches, or five or more fin trenches), a different number of trenches (e.g., more than one trench or isolation region similar to the trench 315), a different number of fins (e.g., one fin, two fins, three fins, four fins, or six or more fins), a different number of inactive fins (e.g., zero inactive fins, one inactive fin, more than two inactive fins), a different number of active fins (e.g., one active fin, two active fins, or four or more active fins, and/or a different number of gate fins (e.g., one gate fin, two gate fins, three gate fins, or more than four gate fins).

FIG. 4 illustrates a partially schematic top view of another high-voltage semiconductor device 400 configured in accordance with various embodiments of the present technology. As shown, the high-voltage semiconductor device 400 is generally similar to the high-voltage semiconductor device 100 of FIG. 1. For example, the high-voltage semiconductor device 400 includes a HVP finFET 401 having (i) a plurality of fin trenches 403 (identified individually in FIG. 4 as fin trenches 403a-403d) formed in active area 409; (ii) a plurality of fins 410 (identified individually in FIG. 4 as fins 410a-410e); (iii) a high-voltage N-well implant 406; (iv) a gate 407 disposed at least partially over the plurality of fin trenches 403 and the plurality of fins 410; (v) P+ implant regions 408; (vi) a contact 405a, and (vii) a contact 405. Consistent with the description of FIGS. 2 and 3 above, the gate 407 can include a plurality of gate fins, each gate fin being positioned within a corresponding one of the fin trenches 403a-403d.

In contrast with the high-voltage semiconductor device 100 of FIG. 1, however, the fin trench 403a of the HVP finFET 401 of the high-voltage semiconductor device 400 in FIG. 4 has a length (measured in a direction extending generally from the contact 405b toward the contact 405a) such that the fin trench 403a extends from (a) an edge of the P+ implant region 408 on a side of the contact 405b opposite the fin trenches 403b and 403c to (b) an edge of the P+ implant region 408 on a side of the contact 405a opposite the fin trenches 403b and 403c. As discussed above, this is expected to make the width of the HVP finFET 401 more well-defined in comparison to embodiments in which the fin trench 403a is constrained to the channel length of the channel of the HVP finFET 401. As indicated by arrows 487 and 488, the fin trench 403d can, in other embodiments, include a length similar to the length of the fin trench 403a illustrated in FIG. 4. Furthermore, as indicated by the arrows 485-488, the fin trenches 403a and 403d can have different (e.g., larger or smaller) lengths from the lengths shown in FIG. 4.

Another difference of the HVP finFET 401 shown in FIG. 4 from the HVP finFET 101 of FIG. 1 includes dimensions of the gate 407. More specifically, rather than a length of the gate 407 matching or being aligned with lengths of the fin trenches 403a-403d, the length of the gate 407 is illustrated as being smaller than the lengths of the fin trenches 403a-403b. In other embodiments, the gate 407 can be positioned and/or the gate 407 can be dimensioned such that top and/or bottom boundary of the gate 407 is (a) aligned with the top and/or bottom boundaries, respectively, of one or more of the fin trenches 210b-210d and/or (b) is positioned between the top and/or bottom boundaries, respectively, of one or more of the fin trenches 210b-210d and one of the contacts 405a or 405b.

As shown in FIG. 4, the fins 410b-410d are configured as active fins while the fins 410a and 410e are configured as inactive (or half) fins. Thus, the fin trenches 403a and 403d can help define an active width of the HVP finFET 401. In other words, the outer fin trenches 403a and 403d can serve as isolation regions (e.g., STI regions, LDT isolation regions) in some embodiments.

As also shown in FIG. 4, the left and right boundaries of the active area 409 extend beyond the left and right boundaries, respectively, of the N-well 406. Thus, the left boundary of the N-well 406 is positioned between (i) the left boundary of the active area 409 and (ii) the left boundary of the gate 407 and/or the left boundary of the fin trench 403a. Similarly, the right boundary of the N-well 406 is positioned between (i) the right boundary of the active area 409 and (ii) the right boundary of the gate 407 and/or the right boundary of the fin trench 403d. Such a configuration is expected to maintain a high breakdown voltage of the HVP finFET 401 and/or the high-voltage semiconductor device 400.

While the HVP finFET 401 of the high-voltage semiconductor device 400 is shown in FIG. 4 and/or described above as having four fin trenches 403a-403d, five fins 410a-410e, two inactive fins 410a and 410e, three active fins 410b-410d, and four gate fins, the present technology is not so limited. In other embodiments, HVP finFETs of high-voltage semiconductor devices configured in accordance with the present technology may include a different number of fin trenches (e.g., one fin trench, two fin trenches, three fin trenches, or five or more fin trenches), a different number of fins (e.g., one fin, two fins, three fins, four fins, or six or more fins), a different number of inactive fins (e.g., zero inactive fins, one inactive fin, more than two inactive fins), a different number of active fins (e.g., one active fin, two active fins, or four or more active fins, and/or a different number of gate fins (e.g., one gate fin, two gate fins, three gate fins, or more than four gate fins).

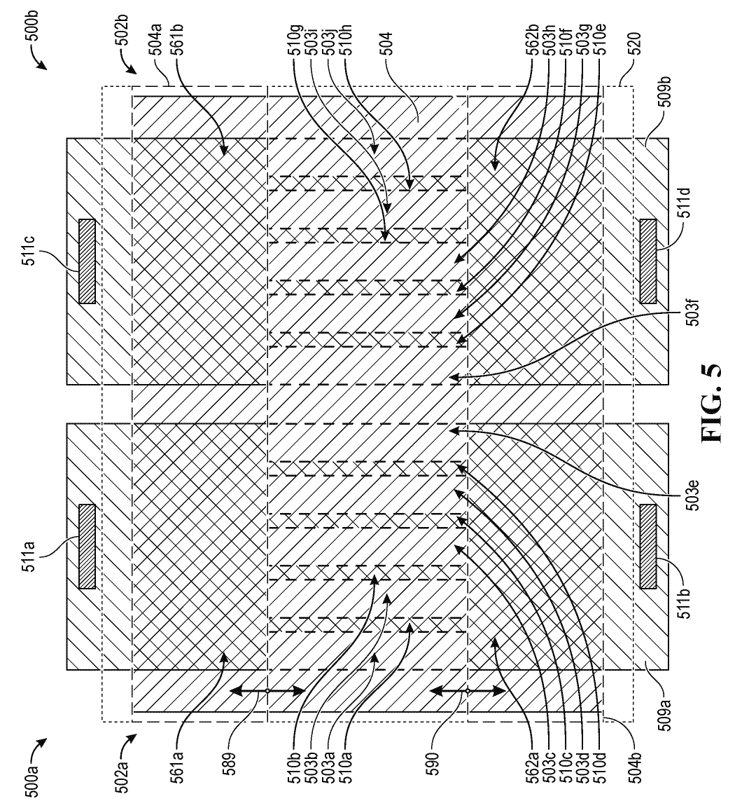

FIG. 5 illustrates a partially schematic top view of a first high-voltage semiconductor device 500a and a second high-voltage semiconductor device 500b arranged adjacent one another, each configured in accordance with various embodiments of the present technology. As shown, the first high-voltage semiconductor device 500a includes a first HVD finFET 502a, and the second high-voltage semiconductor device 500b includes a second HVD finFET 502b. Each of the first and second HVD finFETs 502a and 502b can be generally similar to the HVD finFET 102 described above with reference to FIG. 1. For example, the first HVD finFET 502a can include (i) a plurality of fin trenches 503 (identified individually in FIG. 5 as fin trenches 503a-503e) formed within a first active area 509a; (ii) a plurality of fins 510 (identified individually in FIG. 5 as fins 510a-510d; (iii) a gate 504; (iv) a contact 511a; (v) a contact 511b; and (vi) lightly doped drain (LDD) regions 561a and 562b. Similarly, the second HVD finFET 502b can include (i) a plurality of fin trenches 503 (identified individually as fin trenches 503f-503j) formed within a second active area 509b; (b) a plurality of fins 510 (identified individually in FIG. 5 as fins 510e-510h); (c) the gate 504; (d) a contact 511c; (e) a contact 511d; and (f) LDD regions 561b and 562b.

In the illustrated embodiment, the first and second HVD finFETs 502a and 502b share the gate 504, which extends across the fins 510a-510h, the fin trenches 503a-503j, and the channels of the first and second HVD finFETs 502a and 502b. In other embodiments, the first and second HVD finFETs 502a and 502b can have separate and/or independent gates 504. As shown in FIG. 5, the gate 504 includes (i) a first region 504a that extends over the planar LDD regions 561a and 561b of the first and second HVD finFETs 502a and 502b, respectively, and (ii) a second region 504b that extends over the planar LDD regions 562a and 562b of the first and second HVD finFETs 502a and 502b, respectively. The first and second regions 504a and 504b can be gate LDD implant regions.

In the illustrated embodiment, boundaries of the first and second regions 504a and 504b proximate channels of the first and second HVD finFETs 502a and 502b are aligned with edges of the fin trenches 503a-503j. More specifically, a bottom boundary of the region 504a is aligned with top edges of the fin trenches 503a-503j, and a top boundary of the region 504b is aligned with bottom edges of the fin trenches 503a-503j. As indicated by arrows 589 and 590, the boundaries of the first and second regions 504a and 504b can vary in other embodiments from the positions shown in FIG. 5. Thus, the bottom boundary of the first region 504a can be positioned (a) between the top edge(s) of one or more of the fin trenches 503a-503j and one or more of the contacts 511a and 511c, and/or (b) such that the top edge(s) of one or more of the fin trenches 503a-503j are positioned between the bottom boundary of the first region 504a and one or more of the contacts 511a and 511c. Additionally, or alternatively, the top boundary of the second region 504b can be positioned (a) between the bottom edge(s) of one or more of the fin trenches 503a-503j and one or more of the contacts 511b and 511d, and/or (b) such that the bottom edge(s) of one or more of the fin trenches 503a-503j are positioned between the top boundary of the second region 504b and one or more of the contacts 511b and 511d. For example, as discussed above with reference to FIG. 1, one or more of the fin trenches 503a-503j can be extended into the LDD regions 561a, 561b, 562a, and/or 562b (e.g., such that the LDD regions 561a, 561b, 562a, and/or 562b are finned as opposed to planar). The top boundary of the first region 504a and the bottom boundary of the second region 504b can similarly vary from the positions shown in FIG. 5, such as in directions generally along the arrows 589 and 590.

In the illustrated embodiment, the lengths, widths, and spacing of the fins 510a-510h are uniform across each of the first and second HVD finFETs 502a and 502b and relative to one another. In other embodiments, the lengths, widths, depths, and/or spacing/pitch of the fins 510a-510h (and/or the fin trenches 503a-503j) can vary from that shown in FIG. 5. For example, the lengths, widths, depths, and spacing/pitch of the fins 510a-510h (an/do the fin trenches 503a-503j) can differ across the first HVD finFET 502a, across the second HVD finFET 502b, and/or across the first HVD finFET 502a and the second HVD finFET 502b.

In some embodiments, one or more of the fin trenches 503a-503j can include polysilicon or another suitable material (e.g., formed as gate fins) positioned therein. In these and other embodiments, the arrangement shown in FIG. 5 can omit polysilicon from the region between the fin trenches 503e and 503f. The first high-voltage semiconductor device 500a and the second high-voltage semiconductor device 500b can additionally include a thick oxide layer 520 in some embodiments.

In these and other embodiments, the fin trenches 503e and 503f can serve as isolation regions (e.g., STI regions, LDT isolation regions) that isolate the HVD finFET 502a and the HVD finFET 502b from one another. For example, the first HVD finFET 502a and/or the second HVD finFET 502b can omit polysilicon from within the fin trenches 503e and 503f. In these and still other embodiments, the fin trenches 503a and 503j can serve as isolation regions (e.g., STI regions, LDT isolation regions) that isolate the first HVD finFET 502a and the second HVD finFET 502b, respectively, from adjacent devices and/or components. For example, the first HVD finFET 502a and/or the second HVD finFET 502b can omit polysilicon from within the fin trenches 503a and 503j. Additionally, or alternatively, one or more other isolation regions (e.g., STI regions, LDT isolation regions) can be positioned adjacent the first high-voltage semiconductor device 500a and/or the second high-voltage semiconductor device 500b to isolate the first HVD finFET 502a and/or the second HVD finFET 502b, respectively, from adjacent devices and/or components, such as in addition to or in lieu of using the fin trenches 503a and/or 503j for isolation.

While the first and second HVD finFETs 502a and 502b of the first and second high-voltage semiconductor devices 500a and 500b, respectively, are each shown in FIG. 5 and/or described above as having five fin trenches 503, four fins 510, and three to five gate fins, the present technology is not so limited. In other embodiments, first and/or second HVD finFETs configured in accordance with the present technology may include a different number of fin trenches (e.g., one fin trench, two fin trenches, three fin trenches, four fin trenches, or six or more fin trenches), a different number of fins (e.g., one fin, two fins, three fins, or five or more fins), and/or a different number of gate fins (e.g., one gate fin, two gate fins, three gate fins, four gate fins, five gate fins, or six or more gate fins).

### C.Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. An integrated high-voltage switch, comprising:
a high-voltage p-type fin field effect transistor (HVP finFET), a high-voltage depletion fin field effect transistor (HVD finFET), and an active area extending across both the HVP finFET and the HVD finFET,
wherein the HVP finFET includes—
a first plurality of fin trenches formed in the active area,
a first plurality of fins defined at least in part by the first plurality of fin trenches, wherein a fin of the first plurality of fins is at least partially positioned within a channel of the HVP finFET; and
a first gate extending across the first plurality of fins, wherein the first gate includes at least two first gate fins that are each at least partially positioned within a corresponding one of the first plurality of fin trenches; and
wherein the HVD finFET includes—
a second plurality of fin trenches formed in the active area;
a second plurality of fins defined at least in part by the second plurality of fin trenches, wherein a fin of the second plurality of fins is at least partially positioned within a channel of the HVD finFET; and
a second gate extending across the second plurality of fins, wherein the second gate includes at least two second gate fins that are each at least partially positioned within a corresponding one of the second plurality of fin trenches.

2. The integrated high-voltage switch of claim 1, wherein:
the HVD finFET further includes a planar lightly doped drain (LDD) region; and
the fin of the second plurality of fins is constrained to the channel of the HVD finFET.

3. The integrated high-voltage switch of claim 2, wherein the second gate extends at least partially over the planar LDD region.

4. The integrated high-voltage switch of claim 1, wherein:
the HVD finFET further includes a finned lightly doped drain (LDD) region; and
the fin of the second plurality of fins extends from the channel of the HVD finFET into the finned LDD region.

5. The integrated high-voltage switch of claim 4, wherein the second gate extends at least partially over the finned LDD region.

6. The integrated high-voltage switch of claim 1, wherein:
the HVP finFET further includes (i) a P+ implant region disposed adjacent the channel of the HVP finFET and (ii) a contact disposed over the P+ implant region; and
at least one fin trench of the first plurality of fin trenches extends to a boundary of the P+ implant region on a side of the contact opposite the channel of the HVP finFET.

7. The integrated high-voltage switch of claim 1, wherein:
fins of the first plurality of fins are arranged such that at least one fin of the first plurality of fins is aligned with a first edge of the active area; or
fins of the second plurality of fins are arranged such that at least one fin of the second plurality of fins is aligned with a second edge of the active area.

8. The integrated high-voltage switch of claim 1, wherein:
fins of the first plurality of fins are arranged such that at least one fin of the first plurality of fins is laterally offset from and out of alignment with a first edge of the active area; or
fins of the second plurality of fins are arranged such that at least one fin of the second plurality of fins is laterally offset from and out of alignment with a second edge of the active area.

9. The integrated high-voltage switch of claim 1, wherein at least one fin of the first plurality of fins includes a same length, width, or depth as at least one fin of the second plurality of fins.

10. The integrated high-voltage switch of claim 1, wherein at least one fin of the first plurality of fins includes a different length, a different width, or a different depth from a length, a width, or a depth, respectively of at least one fin of the second plurality of fins.

11. The integrated high-voltage switch of claim 1, wherein:
the HVP finFET further includes an N-well extending at least partway across the channel of the HVP finFET;
the first plurality of fins includes an outer fin trench; and
a boundary of the N-well is positioned (i) on a side of the outer fin trench opposite the channel of the HVP finFET and (ii) between an edge of the active area and the outer fin trench.

12. The integrated high-voltage switch of claim 1, further comprising a local deep trench (LDT) isolation region positioned adjacent the channel of the HVP finFET or the channel of the HVD finFET.

13. A high-voltage semiconductor device, comprising:
an active area;
a plurality of fin trenches formed in the active area;
a plurality of fins (a) defined at least in part by the plurality of fin trenches and (b) at least partially positioned within a channel of the high-voltage semiconductor device; and
a gate extending across the plurality of fins.

14. The high-voltage semiconductor device of claim 13, wherein at least one fin trench of the plurality of fin trenches is constrained to the channel of the high-voltage semiconductor device.

15. The high-voltage semiconductor device of claim 13, wherein:
the high-voltage semiconductor device further comprises a P+ implant region disposed adjacent the channel; and
at least one fin trench of the plurality of fin trenches extends from the channel into the P+ implant region.

16. The high-voltage semiconductor device of claim 13, wherein:
the high-voltage semiconductor device further comprises an N-well; and
the plurality of fins includes an outer fin trench; and
a boundary of the N-well is positioned (i) on a side of the outer fin trench opposite the channel and (ii) between an edge of the active area and the outer fin trench.

17. A high-voltage semiconductor device, comprising:
an active area;
a plurality of fin trenches formed in the active area;
a plurality of fins (a) defined at least in part by the plurality of fin trenches and (b) at least partially positioned within a channel of the high-voltage semiconductor device;
a gate extending across the plurality of fins; and
a lightly doped drain (LDD) region disposed adjacent the channel.

18. The high-voltage semiconductor device of claim 17, wherein the gate extends at least partially over the LDD region.

19. The high-voltage semiconductor device of claim 17, wherein the plurality of fin trenches are constrained to the channel such that the LDD region is a planar LDD region.

20. The high-voltage semiconductor device of claim 17, wherein at least one fin trench of the plurality of fin trenches extends from the channel into the LDD region such that the LDD region is a finned LDD region.
